(19) United States
(12) Patent Application Publication
(10) Pub. No.: US 2006/0180906 A1
(43) Pub. Date: Aug. 17, 2006

(54) Chip package and producing method thereof

(75) Inventor: Yi-Chuan Ding, Kaohsiung City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Advanced Semiconductor Engineering, Inc.

(21) Appl. No.: 11/296,880

(22) Filed: Dec. 8, 2005

(30) Foreign Application Priority Data
Feb. 17, 2005 (TW) 94104698

(51) Int. Cl. H01L 23/02

(52) U.S. Cl. 257/678

(57) ABSTRACT

A chip package and a producing method thereof are provided. The producing method of the chip package includes following steps. First, a bottom surface of a chip is disposed on a carrier, and a top surface of the chip is wire-bonded to the carrier. Then, a first molding compound is formed on an edge of the top surface of the chip to protect the edge. Afterwards, a second molding compound is formed to encapsulate the chip, the first molding compound and part of the carrier.

This application claims the benefit of Taiwan application Serial No. 94104698, filed Feb. 17, 2005, the subject matter of which is incorporated herein by reference.

### BACKGROUND OF THE INVENTION

1. Field of the Invention

The invention relates in general to a chip package and a producing method thereof, and more particularly to a low-K chip package and a producing method thereof.

2. Description of the Related Art

A conventional chip package includes a substrate, a chip, a wire and a molding compound. The chip is adhesively disposed on the substrate with an active surface of the chip opposite to the substrate. The wire is used for connecting a pad of the active surface of the chip with a gold finger on a surface of the substrate, to electrically connect the chip and the substrate. The molding compound is used for covering the chip, the wire and part of the surface of the substrate, for protecting the electrical connection between the chip and the substrate.

However, the material of the chip in the conventional chip package is brittle, and the coefficient of the thermal expansion (CTE) of the chip does not match that of the molding compound. As a result, an edge of the chip cracks easily. This problem occurs more often in a low-K chip. However, the low-K chips are used widely due to the properties of better electrical performance and faster signal transmission speed. Therefore, how to solve the problem that the edge of the chip cracks easily becomes an important issue.

### SUMMARY OF THE INVENTION

It is therefore an object of the invention to provide a chip package and a producing method thereof. A first molding compound is used for covering an edge of a top surface of a chip. A second molding compound is used for encapsulating the chip, the first molding compound and part of a carrier. Therefore, the first molding compound can protect the edge of the top surface of the chip, for avoiding the edge of the top surface of the chip cracking easily.

The invention achieves the above-identified objects by providing a chip package including a carrier, a chip, a first molding compound and a second molding compound. The chip has a top surface and a bottom surface. The bottom surface of the chip is disposed on the carrier, and the top surface of the chip is wire-bonded to the carrier. The first molding compound covers an edge of the top surface of the chip, for protecting the edge. The second molding compound encapsulates the chip, the first molding compound and part of the carrier.

The invention achieves the above-identified objects by providing a producing method of a chip package. First, a carrier is provided. Then, a chip is disposed on the carrier. Next, a top surface of the chip is wire-bonded to the carrier. Afterwards, a first molding compound is formed on an edge of the top surface of the chip, for protecting the edge. Then, a second molding compound is formed to encapsulate the chip, the first molding compound and part of the carrier.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A illustrates a sectional view of a chip package according to a preferable embodiment of the invention;

FIG. 1B illustrates a sectional view of another chip package according to the preferable embodiment of the invention;

FIG. 2A illustrates a top view of the first molding compound annularly covering the top surface of the chip;

FIG. 2B illustrates a top view of the first molding compound covering several corners of the top surface of the chip; and

FIG. 3 illustrates a producing method of a chip package according to the preferable embodiment of the invention.

### DETAILED DESCRIPTION OF THE INVENTION

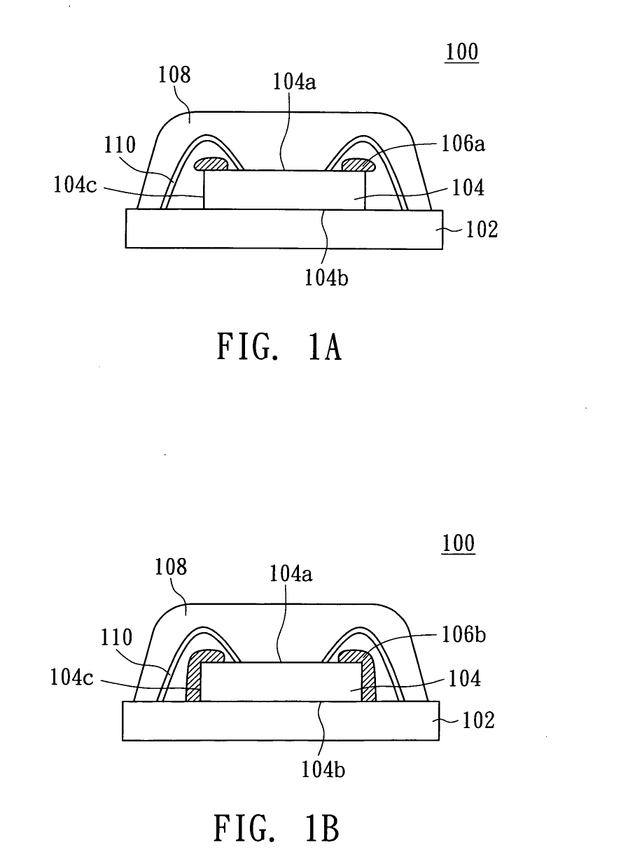

Please referring to FIG. 1A, a sectional view of a chip package according to a preferable embodiment of the invention is illustrated. The chip package 100 includes a carrier 102, a chip 104, a first molding compound and a second molding compound 108. The carrier 102, for example, can include a circuit board. The chip 104 has a top surface 104a, a bottom surface 104b and an external wall 104c. The external wall 104c connects the top surface 104a and the bottom surface 104b. For example, the chip 104 can be a low-K chip. The bottom surface 104b is disposed on the carrier 102, and the top surface 104a is electrically connected to the carrier 102 through a wire 110. The first molding compound covers an edge of the top surface 104a. As shown in FIG. 1A, the first molding compound can be a flat molding compound 106a. The flat molding compound 106a protrudes outwards from the edge of the top surface 104a, for protecting the edge. The first molding compound, for example, can have a low module, for absorbing a stress applied to the edge of the top surface 104a. The second molding compound 108 encapsulates the chip 104, the first molding compound and part of the carrier 102.

Please referring to FIG. 1B, a sectional view of another chip package according to the preferable embodiment of the invention is illustrated. As shown in FIG. 1B, the first molding compound can be a turning molding compound 106b. The turning molding compound 106b protrudes outwards from the edge of the top surface 104a of the chip 104 and turns down extendedly toward the external wall 104c of the chip 104. The external wall 104c and the top surface 104a form a turning connection part. The turning molding compound 106b covers the turning connection part.

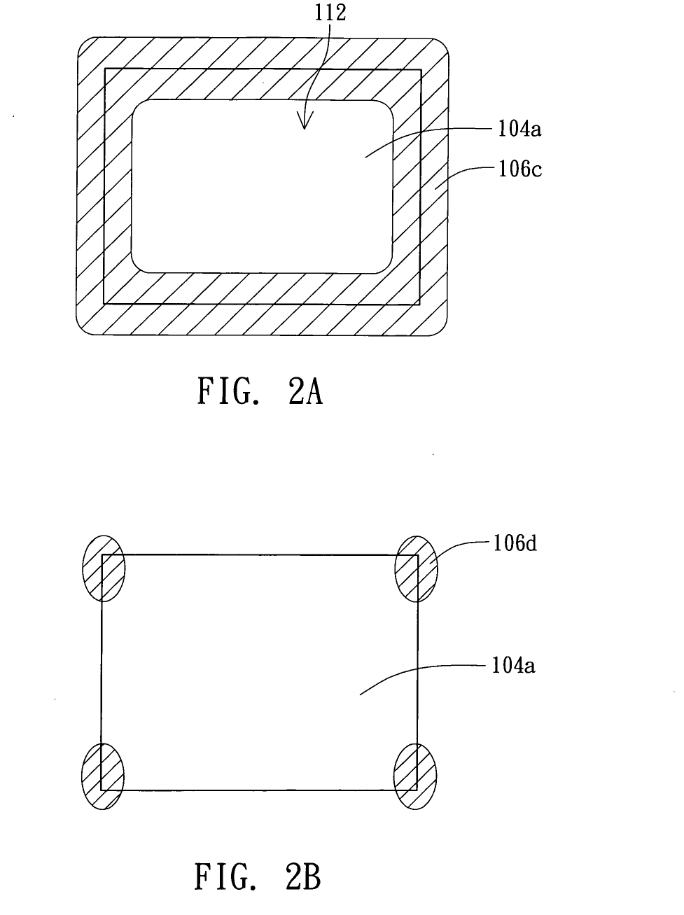

In order to illustrate more about how the first molding compound covers the top surface 104a, please refer to FIG. 2A. FIG. 2A illustrates a top view of the first molding compound annularly covering the top surface of the chip. The first molding compound 106c encompasses the chip to form an opening 112. The opening 112 is corresponding to the top surface 104a of the chip, for enabling the first molding compound 106c to cover the surrounding edges of the top surface 104a. The first molding compound 106c is used for protecting the surrounding edges of the top surface 104a. The first molding compound 106c can protrude outwards from the surrounding edges of the top surface 104a flatly, as shown in FIG. 1A. As a result, the first molding compound forms a flat annular molding compound. Or, the first molding compound can protrude outwards from the surrounding edges and turn down toward the external wall 104c extendedly. As a result, the first molding compound can form a turning annular molding compound as shown in FIG. 1B. Please referring to FIG. 2B, a top view of the first molding compound covering several corners of the top surface of the chip is illustrated. The first molding compound 106d covers several corners of the top surface 104a. The corners of the top surface 104a are positioned on the edge of the top surface 104a. As a result, the first molding compound 106d can protect the corners of the top surface 104a. The first molding compound 106d can protrude outwards from the corners flatly as shown in FIG. 1A. Or, the first molding compound can protrude outwards from the corners of the top surface 104a and turn down toward the external wall 104c extendedly.

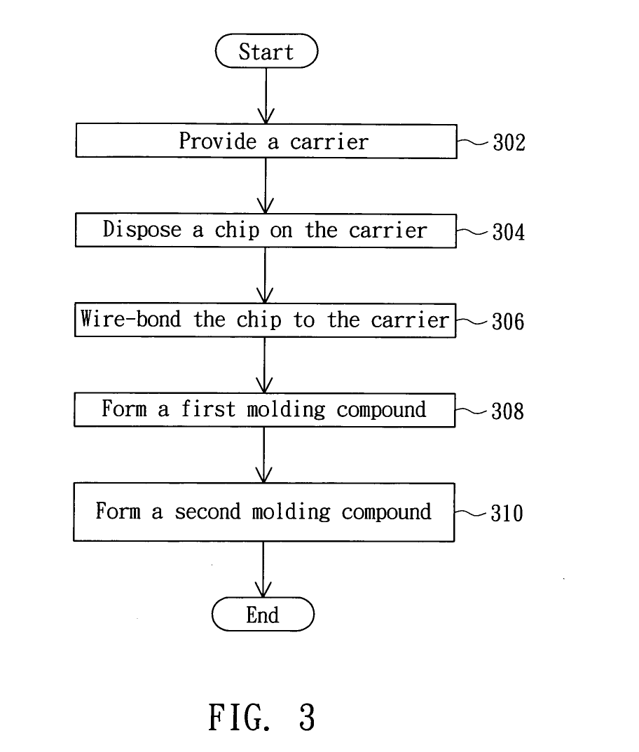

Pease referring to both FIG. 1A and FIG. 3, FIG. 3 illustrates a producing method of a chip package according to the preferable embodiment of the invention. The producing method of the chip package includes following steps. First, the carrier 102 is provided in step 302. Then, the chip 104 is disposed on the carrier 102 in step 304. Next, the top surface 104a of the chip 104 is wire-bonded to the carrier 102 in step 306. Afterwards, the first molding compound is formed on the edge of the top surface 104a, for protecting the edge. For example, the step of forming the first molding compound is a step of forming the flat molding compound 106a as shown in FIG. 1A, or a step of forming the turning molding compound 106b as shown in FIG. 1B. The first molding compound can encompass the chip to form an opening 112 corresponding to the top surface 104a, as shown in FIG. 2A. As a result, a flat annular molding compound or a turning annular molding compound is formed. Or, as shown in FIG. 2B, the first molding 106d covers several corners of the top surface 104a. Then, the second molding compound 108 is formed for encapsulating the chip 104, the first molding compound and part of the carrier 102.

The chip package described in the embodiment of the invention has the first molding compound covering the edge of the top surface of the chip. As a result, the first molding compound can protect the edge of the top surface of the chip. Therefore, the problem that the edge of the top surface of the conventional chip cracks easily due to the brittle material can be solved effectively. Moreover, a molding compound having a low module can be used as the first molding compound, for absorbing the stress applied to the edge of the top surface of the chip to provide the better protection.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A chip package comprising:
a carrier;
a chip having a top surface and a bottom surface, wherein the bottom surface is disposed on the carrier, and the top surface is wire-bonded to the carrier;
a first molding compound for covering an edge of the top surface to protect the edge; and
a second molding compound for encapsulating the chip, the first molding compound and part of the carrier.

2. The package according to claim 1, wherein the first molding compound protrudes outwards from the edge.

3. The package according to claim 1, wherein the first molding compound protrudes outwards from the edge and extendedly turns downwards.

4. The package according to claim 1, wherein the chip further comprises:
an external wall, wherein the external wall and the top surface form a turning connection part, and the first molding compound encapsulates the turning connection part.

5. The package according to claim 1, wherein the first molding compound encompasses the chip to form an opening corresponding to the top surface of the chip.

6. The package according to claim 1, wherein the first molding compound is a flat annular molding compound.

7. The package according to claim 1, wherein the first molding compound covers a plurality of corners of the top surface, and the corners are positioned on the edge.

8. The package according to claim 1, wherein the first molding compound is a turning annular molding compound.

9. The package according to claim 1, wherein the first molding compound has a low module to absorb a stress applied to the edge.

10. The package according to claim 1, wherein the chip is a low-K chip.

11. The package according to claim 1, wherein the carrier comprises a circuit board.

12. A producing method of a chip package comprising:
providing a carrier;
disposing a chip on the carrier;
wire-bonding a top surface of the chip to the carrier;
forming a first molding compound on an edge of the top surface to protect the edge; and
forming a second molding compound to encapsulate the chip, the first molding compound and part of the carrier.

13. The method according to claim 12, wherein the first molding compound protrudes outwards from the edge in the step of forming the first molding compound.

14. The method according to claim 12, wherein the first molding compound protrudes outwards from the edge and turns downwards extendedly in the step of forming the first molding compound.

15. The method according to claim 12, wherein the first molding compound encapsulates a turning connection part positioned on a join of an external wall and the top surface in the step of forming the first molding compound

16. The method according to claim 12, wherein the first molding compound encompasses the chip to form an opening corresponding to the top surface of the chip in the step of forming the first molding compound.

17. The method according to claim 12, wherein the first molding compound covers a plurality of corners of the top surface in the step of forming the first molding compound, wherein the corners are positioned on the edge.

18. The method according to claim 12, wherein the first molding compound has a low module to absorb a stress applied to the edge.

19. The method according to claim 12, wherein the chip is a low-K chip.

20. The method according to claim 12, wherein the carrier comprises a circuit board.
